(19) United States
(12) Patent Application Publication
(10) Pub. No.: US 2009/0115546 A1
(43) Pub. Date: May 7, 2009

(54) MODULATOR COMPRISING A DUAL-FREQUENCY OSCILLATOR AND A SYNTHESIZER

(75) Inventors: Anthony KERSELAERS, Leuven (BE); Felix ELSEN, Leuven (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/571,577

(22) PCT Filed: Jul. 1, 2005
(86) PCT No.: PCT/IB05/52196

§ 371 Date: Jan. 3, 2007

(30) Foreign Application Priority Data
Jul. 13, 2004 (EP) 04103322.6

(51) Int. Cl. H03C 3/09; H03B 25/00

(52) U.S. Cl. 332/135; 331/60

(57) ABSTRACT

Oscillators (10) which oscillate at a fundamental frequency also generate harmonics. The fundamental frequency or a lower harmonic is used for feedback purposes, and a harmonic higher than either the fundamental frequency or the lower harmonic is used for output purposes. As a result, the oscillators (10) operate at a lower frequency than an output frequency and are low cost. Synthesizers (20) coupled to the oscillators (10) also operate at this lower frequency, and modulators (5) comprising such oscillators (10) and synthesizers (20) are low cost. A lower power consumption and less sensitivity to disturbing fields are further advantages. Filtering has become less complicated, and a smaller number of components has resulted in smaller dimensions. The oscillators (10) comprise tuning circuits (11) and amplifiers (12), which amplifiers (12) are fed back via feedback circuits (13). Such an amplifier (12) may comprise just a single transistor (40).

The invention relates to a device comprising a modulator, which modulator comprises an oscillator and a synthesizer, and also relates to a modulator comprising an oscillator and a synthesizer, and to an oscillator.

Examples of such a device are wireless (digital) speaker systems, wireless (digital) headphones, babyphones and further consumer products.

A prior art modulator is known from U.S. Pat. No. 5,281,930, which discloses in its FIG. 1 a voltage controlled oscillator receiving a modulating signal via a weighting filter and receiving a tuning signal via a low-pass filter from a phase comparator. The phase comparator compares a divided output signal of the voltage controlled oscillator with a reference signal generator. To divide the output signal of the voltage controlled oscillator, a divider is used. This combination of the phase detector and the divider can be replaced by a synthesizer.

A known modulator comprising an oscillator and a synthesizer is disadvantageous, inter alia, owing to the fact that this modulator is relatively expensive: either the oscillator and the synthesizer need to be operated at the high modulation frequency, which makes the oscillator and the synthesizer expensive, or the oscillator and the synthesizer are operated at for example half the modulation frequency, in which case an additional frequency doubler is required. In both cases, the modulator itself as well as the device comprising this modulator become relatively expensive.

It is an object of the invention, inter alia, to provide a relatively low cost device.

Furthers objects of the invention are, inter alia, to provide a modulator and an oscillator for use in a relatively low cost device.

The device according to the invention comprises a modulator, which modulator comprises an oscillator and a synthesizer, which oscillator comprises
a first oscillator input for receiving a tuning signal from the synthesizer;
a second oscillator input for receiving a modulation signal;
a first oscillator output for supplying a first output signal comprising a first frequency to the synthesizer; and
a second oscillator output for supplying a second output signal comprising a second frequency to a modulator output;
   which first frequency is either a fundamental frequency or a harmonic thereof and which second frequency is higher than the first frequency and a harmonic of the fundamental frequency.

Each oscillator, when oscillating at a fundamental frequency, generates a fundamental frequency signal, but also generates a first harmonic signal, a second harmonic signal etc. The fundamental frequency signal (or the first harmonic signal etc.) can be used as a first output signal, and the first harmonic signal (or the second harmonic signal etc.) can be used as a second output signal. By providing the oscillator with two oscillator outputs, a first oscillator output for generating the first low frequency output signal and a second oscillator output for generating the second high frequency output signal, the first low frequency output signal is supplied to the synthesizer and the second high frequency output signal is transmitted. As a result, the oscillator and the synthesizer can operate at a low frequency, and the modulator and the device remain low cost.

The device according to the invention is further advantageous in that the oscillator and the synthesizer, when operating at a lower frequency, have a lower power consumption and are less sensitive to disturbing fields. Filtering becomes less complicated, and a smaller number of components results in smaller dimensions.

An embodiment of the device according to the invention is defined by the oscillator further comprising
a tuning circuit comprising the first and second oscillator inputs and a tuning circuit output; and
an amplifier comprising the first and second oscillator outputs and an amplifier input coupled to the tuning circuit output, which amplifier is fed back via a feedback circuit. The tuning circuit takes care of tuning the oscillator in response to the tuning signal received via the first oscillator input, and takes care of modulating the oscillator by the modulation signal, such as for example an audio signal and/or a video signal. The amplifier forms a buffer and has an amplification factor “one”. This amplification factor is adjusted via the feedback circuit.

An embodiment of the device according to the invention is defined by the amplifier comprising a transistor with a control electrode constituting the amplifier input, and with first and second main electrodes constituting the oscillator outputs. Such an amplifier in the form of a single transistor performs well and is extremely low cost.

An embodiment of the device according to the invention is defined by the feedback circuit comprising a first capacitor coupled to the first main electrode and the control electrode and comprising a second capacitor coupled to the first main electrode and ground. These first and second capacitors form a voltage divider which does not dissipate real power, only imaginary power.

An embodiment of the device according to the invention is defined by the oscillator further comprising an output circuit coupled to the second main electrode for suppressing the first frequency. By suppressing the first frequency (amplitude=0-10% of the original amplitude) and by not suppressing the second frequency (amplitude=90-100% of the original amplitude), the second frequency can be easily supplied to the modulator output.

An embodiment of the device according to the invention is defined by the output circuit comprising a serial circuit of a third capacitor and an inductor coupled to the second main electrode and to ground, a fourth capacitor coupled in parallel to the serial circuit, and a resistor coupled to the second main electrode and to a supply terminal. Such an output circuit performs well and is extremely low cost.

An embodiment of the device according to the invention is defined by the tuning circuit comprising a parallel circuit of a further inductor and a fifth capacitor coupled to ground and to a common point of a sixth capacitor and a seventh capacitor, the sixth capacitor further being coupled to the control electrode and the seventh capacitor further being coupled to the first oscillator input via a varicap diode, the control electrode further being coupled via a further diode to the second oscillator input which is further coupled to ground via an eighth capacitor. Such a tuning circuit performs well and is extremely low cost.

The modulator according to the invention comprises an oscillator and a synthesizer, which oscillator comprises
a first oscillator input for receiving a tuning signal from the synthesizer;
a second oscillator input for receiving a modulation signal;
a first oscillator output for supplying a first output signal comprising a first frequency to the synthesizer; and
a second oscillator output for supplying a second output signal comprising a second frequency to a modulator output;
   which first frequency is either a fundamental frequency or a harmonic thereof and which second frequency is higher than the first frequency and a harmonic of the fundamental frequency.

The oscillator according to the invention comprises
a first oscillator input for receiving a tuning signal from a synthesizer;
a second oscillator input for receiving a modulation signal;
a first oscillator output for supplying a first output signal comprising a first frequency to the synthesizer; and
a second oscillator output for supplying a second output signal comprising a second frequency to a modulator output;
   which first frequency is either a fundamental frequency or a harmonic thereof and which second frequency is higher than the first frequency and a harmonic of the fundamental frequency.

Embodiments of the modulator according to the invention and of the oscillator according to the invention correspond with the embodiments of the device according to the invention.

The invention is based upon an insight, inter alia, that each oscillator, when oscillating at a fundamental frequency, generates a fundamental frequency signal, but also generates a first harmonic signal, a second harmonic signal etc., and is based upon a basic idea, inter alia, that a first output signal comprising a first frequency, which first frequency is either a fundamental frequency or a harmonic thereof, is to be used for feedback purposes, and a second output signal comprising a second frequency, which second frequency is higher than the first frequency and a harmonic of the fundamental frequency, is to be used for output purposes.

The invention solves the problem, inter alia, to provide a relatively low cost device, and is advantageous, inter alia, in that the oscillator and the synthesizer, when operating at a lower frequency, have a lower power consumption and are less sensitive to disturbing fields. Filtering becomes less complicated, and a smaller number of components results in smaller dimensions.

These and other aspects of the invention will be apparent from and elucidated with reference to the embodiments(s) described hereinafter.

In the drawings:

FIG. 1 shows diagrammatically a device according to the invention comprising a modulator according to the invention;

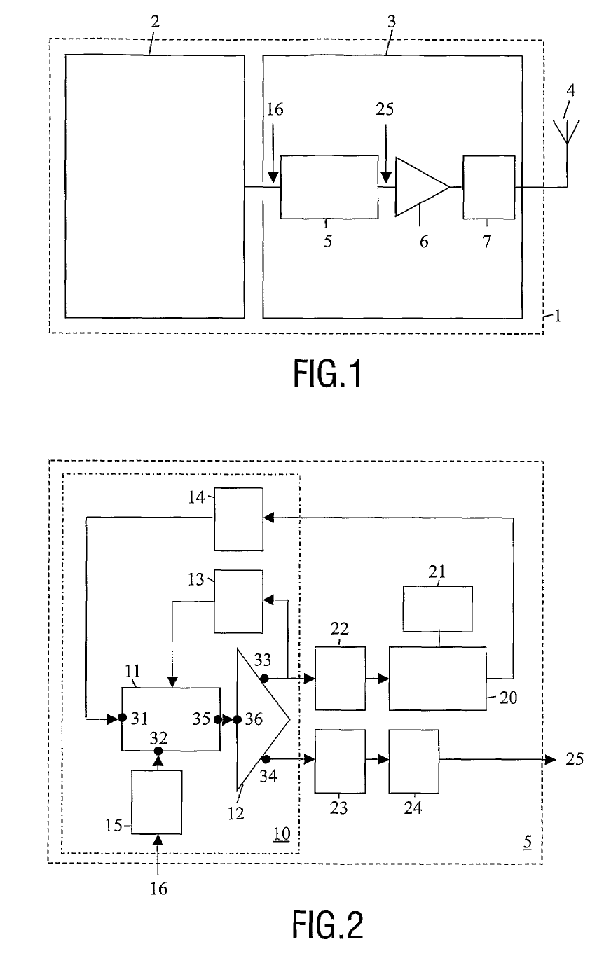

FIG. 2 shows diagrammatically a modulator according to the invention comprising an oscillator according to the invention; and

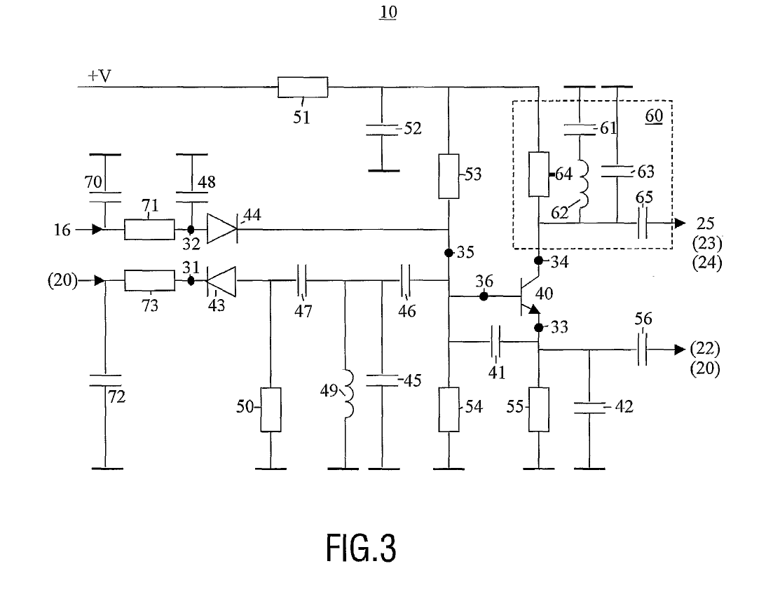

FIG. 3 shows diagrammatically an oscillator according to the invention in greater detail.

The device 1 according to the invention shown in FIG. 1 such as for example a wireless (digital) speaker system, a wireless (digital) headphone, a babyphone or a further consumer product etc. comprises a low-frequency module 2 and a high-frequency module 3 coupled to an antenna 4. The high-frequency module 3 comprises a modulator 5 according to the invention. The modulator 5 comprises a modulator input 16 for receiving a modulation signal from the low-frequency module and a modulation output 25 coupled via a power amplifier 6 and a filter 7 to the antenna 4.

The modulator 5 according to the invention shown in FIG. 2 comprises an oscillator 10 according to the invention. The oscillator 10 comprises a tuning circuit 11 with a first oscillator input 31 and with a second oscillator input 32 and with a tuning circuit output 35 coupled to an amplifier input 36 of an amplifier 12. The amplifier 12 comprises a first oscillator output 33 coupled via a feedback circuit 13 and the tuning circuit 11 to the amplifier input 36 and comprises a second oscillator output 34. The modulator 5 further comprises a synthesizer 20 with a synthesizer input coupled via a leveling block 22 to the first oscillator output 33 and with a synthesizer output coupled via a filter 14 to the first oscillator input 31. The second oscillator input 32 is coupled via a filter 15 to the modulator input 15, and the second oscillator output 34 is coupled via a filter 23 and a leveling block 24 to the modulator output 25. The synthesizer 20 is further coupled to a reference generator 21.

The oscillator 10 according to the invention shown in FIG. 3 in greater detail comprises a transistor 40 having a first main electrode (emitter) constituting the first oscillator output 33 and having a second main electrode (collector) constituting the second oscillator output 34 and having a control electrode (basis) constituting the amplifier input 36. The transistor 40 is a possible embodiment for realizing the amplifier 12, without excluding further embodiments. The emitter is coupled via a first capacitor 41 to the basis and via a second capacitor 42 to ground. These capacitors 41,42 are a possible embodiment for realizing the feedback circuit 13, without excluding further embodiments. The collector is coupled to an output circuit 60 comprising a serial circuit of a third capacitor 61 and an inductor 62 coupled to the collector and to ground, a fourth capacitor 63 coupled in parallel to the serial circuit, and a resistor 64 coupled to the collector and to a supply terminal +V via a resistor 51.

The oscillator 10 further comprises a parallel circuit of a further inductor 49 and a fifth capacitor 45 coupled to ground and to a common point of a sixth capacitor 46 and a seventh capacitor 47. The sixth capacitor 46 is further coupled to the basis and the seventh capacitor 47 is further coupled to the first oscillator input 31 via a varicap diode 43 (cathode=first oscillator input 31). The basis is further coupled via a further diode 44 to the second oscillator input 32 which is further coupled to ground via an eighth capacitor 48 (anode=second oscillator input 32; cathode=tuning circuit output 35). These elements 43-49 are a possible embodiment for realizing the tuning circuit 11, without excluding further embodiments.

The first oscillator input 31 is coupled via a resistor 73 to the synthesizer 20, which resistor 73 is further coupled to ground via a capacitor 72. These elements 72,73 are a possible embodiment for realizing the filter 14, without excluding further embodiments. The second oscillator input 32 is coupled via a resistor 71 to the modulator input 16, which resistor 71 is further coupled to ground via a capacitor 70. These elements 70,71 are a possible embodiment for realizing the filter 15, without excluding further embodiments.

A common point of the resistors 51 and 64 is coupled to ground via a capacitor 52 and via two serial resistors 53 and 54, with a common point of the resistors 53 and 54 being coupled to the basis for DC setting the transistor 40. The emitter is coupled to ground via a resistor 55 for guiding DC currents and is coupled to the leveling block 22 and/or the synthesizer 20 via a capacitor 56. The collector is coupled to the filter 23 and/or to the leveling block 24 and/or to the modulator output 25 via a capacitor 65. A common point of the varicap diode 43 (anode) and the capacitor 47 is coupled to ground via a resistor 50 for, together with the resistor 73, DC setting the varicap diode 43.

Each oscillator 10, when oscillating at a fundamental frequency, generates a fundamental frequency signal, but also generates a first harmonic signal, a second harmonic signal etc. The first oscillator input 31 receives a tuning signal from the synthesizer 20. The second oscillator input 32 receives a modulation signal such as for example an audio signal or a video signal which is to be used for modulating the oscillator 10. Then a resulting modulated signal is to be transmitted via the antenna 4. The first oscillator output 33 supplies a first output signal comprising a first frequency to the synthesizer 20. The second oscillator output 34 supplies a second output signal comprising a second frequency to the modulator output 25. The first frequency is either a fundamental frequency or a harmonic thereof and the second frequency is higher than the first frequency and a harmonic of this fundamental frequency. The fundamental frequency signal (or the first harmonic signal etc.) is then used as the first output signal, and the first harmonic signal (or the second harmonic signal etc.) is then used as the second output signal. By providing the oscillator 10 with two oscillator outputs, a first oscillator output 33 for generating the first lower frequency output signal and a second oscillator output 34 for generating the second higher frequency output signal, the first lower frequency output signal is supplied to the synthesizer 20 and the second higher frequency output signal is transmitted. This is done by suppressing, at the first oscillator output 33, the second higher frequency and by suppressing, at the second oscillator output 34, the first lower frequency, as explained in greater detail below. As a result, the oscillator 10 and the synthesizer 20 can operate at a low frequency, and the modulator 5 and the device 1 remain low cost.

The tuning circuit 11 takes care of tuning the oscillator 10 in response to the tuning signal received via the first oscillator input 31, and takes care of modulating the oscillator 10 by the modulation signal. The amplifier 12 forms a buffer and has an amplification factor “one”. This amplification factor is adjusted via the feedback circuit 13 comprising the first and second capacitors 41 and 42. They form a voltage divider which does not dissipate real power, only imaginary power.

At the collector, the output circuit 60 suppresses the first frequency. By suppressing the first frequency (amplitude=0-10% of the original amplitude) and by not suppressing the second frequency (amplitude=90-100% of the original amplitude), the second frequency can be easily supplied to the modulator output 25. To suppress the first frequency, the capacitor 61 and the inductor 62 have a resonance frequency which is substantially equal to this first frequency. At this resonance frequency, the (frequency dependent) impedance of the serial circuit of the capacitor 61 and the inductor 62 is small compared to the impedance value of the resistor 64. These elements 61-64 are a possible embodiment for realizing the output circuit 60, without excluding further embodiments.

At the emitter, the second frequency is suppressed. By suppressing the second frequency (amplitude=0-20% of the original amplitude) and by not suppressing the first frequency (amplitude=80-100% of the original amplitude), the first frequency can be easily supplied to the synthesizer 20. To suppress the second frequency, the (frequency dependent) impedance present at the emitter resulting from the transistor 40 and from the elements coupled to its basis plays an important role. At the second frequency, this (frequency dependent) impedance is small compared to the impedance value of the resistor 55.

The tuning of the oscillation frequency or fundamental frequency is done by supplying a tuning voltage for example from the synthesizer 20 to the varicap diode 43. The oscillation frequency or fundamental frequency is defined by the elements 41-49. The modulating of the oscillator 10 by the modulation signal is done by the further diode 44.

The oscillator inputs 31,32 are located at the outputs of the filters 14,15, but may alternatively be located at the inputs of these filters 14,15. The oscillator output 33 is located at the input of the leveling block 22, but may alternatively be located at the output of the leveling block 22. The oscillator output 34 is located at the input of the filter 23, but may alternatively be located at the output of the filter 23 or at the output of the leveling block 24. In other words, the filters 14 and 15 may be integrated into the tuning circuit 11, and the filter 23 and the leveling blocks 22 and 24 may be integrated into the amplifier 12, without departing from the scope of this invention. Under certain circumstances, the filters 14, 15 and/or 23 and/or the leveling blocks 22 and/or 24 may be omitted.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. In the device claim enumerating several means, several of these means may be embodied by one and the same item of hardware. The mere fact that certain measures are recited in mutually different dependent claims does not indicate that a combination of these measures cannot be used to advantage.

1. Device (1) comprising a modulator (5), which modulator (5) comprises an oscillator (10) and a synthesizer (20), which oscillator (10) comprises
a first oscillator input (31) for receiving a tuning signal from the synthesizer (20);
a second oscillator input (32) for receiving a modulation signal;
a first oscillator output (33) for supplying a first output signal comprising a first frequency to the synthesizer (20); and
a second oscillator output (34) for supplying a second output signal comprising a second frequency to a modulator output (25);
which first frequency is either a fundamental frequency or a harmonic thereof and which second frequency is higher than the first frequency and a harmonic of the fundamental frequency.

2. Device (1) according to claim 1, the oscillator (10) further comprising
a tuning circuit (11) comprising the first and second oscillator inputs (31,32) and a tuning circuit output (35); and
an amplifier (12) comprising the first and second oscillator outputs (33,34) and an amplifier input (36) coupled to the tuning circuit output (35), which amplifier (12) is fed back via a feedback circuit (13).

3. Device (1) according to claim 2, the amplifier (12) comprising a transistor (40) with a control electrode constituting the amplifier input (36), and with first and second main electrodes constituting the oscillator outputs (33,34).

4. Device (1) according to claim 3, the feedback circuit (13) comprising a first capacitor (41) coupled to the first main electrode and the control electrode and comprising a second capacitor (42) coupled to the first main electrode and ground.

5. Device (1) according to claim 4, the oscillator (10) further comprising an output circuit (60) coupled to the second main electrode for suppressing the first frequency.

6. Device (1) according to claim 5, the output circuit (60) comprising a serial circuit of a third capacitor (61) and an inductor (62) coupled to the second main electrode and to ground, a fourth capacitor (63) coupled in parallel to the serial circuit, and a resistor (64) coupled to the second main electrode and to a supply terminal.

7. Device (1) according to claim 6, the tuning circuit (11) comprising a parallel circuit of a further inductor (49) and a fifth capacitor (45) coupled to ground and to a common point of a sixth capacitor (46) and a seventh capacitor (47), the sixth capacitor (46) further being coupled to the control electrode and the seventh capacitor (47) further being coupled to the first oscillator input (31) via a varicap diode (43), the control electrode further being coupled via a further diode (44) to the second oscillator input (32) which is further coupled to ground via an eighth capacitor (48).

8. Modulator (5) comprising an oscillator (10) and a synthesizer (20), which oscillator (10) comprises
a first oscillator input (31) for receiving a tuning signal from the synthesizer (20);
a second oscillator input (32) for receiving a modulation signal;
a first oscillator output (33) for supplying a first output signal comprising a first frequency to the synthesizer (20); and
a second oscillator output (34) for supplying a second output signal comprising a second frequency to a modulator output (25);
which first frequency is either a fundamental frequency or a harmonic thereof and which second frequency is higher than the first frequency and a harmonic of the fundamental frequency.

9. Oscillator (10) comprising
a first oscillator input (31) for receiving a tuning signal from a synthesizer (20);
a second oscillator input (32) for receiving a modulation signal;
a first oscillator output (33) for supplying a first output signal comprising a first frequency to the synthesizer (20); and
a second oscillator output (34) for supplying a second output signal comprising a second frequency to a modulator output (25);
which first frequency is either a fundamental frequency or a harmonic thereof and which second frequency is higher than the first frequency and a harmonic of the fundamental frequency.
